(19) United States
(12) Patent Application Publication
(10) Pub. No.: US 2024/0353350 A1
(43) Pub. Date: Oct. 24, 2024

(54) WAFER ABNORMALITY DETECTION METHOD AND A SEMICONDUCTOR DEVICE MANUFACTURING METHOD USING THE SAME

(71) Applicant: SAMSUNG ELECTRONICS CO., LTD., Suwon-Si (KR)

(72) Inventors: Kihong CHUNG, Suwon-si (KR); Gucheol KWON, Suwon-si (KR); Jaejoon KIM, Suwon-si (KR); Haemin JEONG, Suwon-si (KR); Minjae HUH, Suwon-si (KR); Hidong KWAK, Suwon-si (KR); Taejung PARK, Suwon-si (KR); Jihye LEE, Suwon-si (KR); Choonshik LEEM, Suwon-si (KR)

(21) Appl. No.: 18/626,396

(22) Filed: Apr. 4, 2024

(30) Foreign Application Priority Data
Apr. 19, 2023 (KR) 10-2023-0051432
Jul. 11, 2023 (KR) 10-2023-0090029

(51) Int. Cl. G01N 21/95; G01N 21/21; G01N 21/88; H01L 21/66

(52) U.S. Cl. CPC G01N 21/9501; G01N 21/211; G01N 21/8851; H01L 22/12; G01N 2021/8887

(57) ABSTRACT

A wafer abnormality detection method including: calculating a residual spectrum between a measured spectrum for a wafer and a predicted spectrum for the wafer; and performing machine learning to determine whether measurement data, which corresponds to the residual data, is abnormal.

### CROSS-REFERENCE TO RELATED APPLICATIONS

This application claims priority under 35 U.S.C. § 119 to Korean Patent Application Nos. 10-2023-0051432, filed on Apr. 19, 2023, and 10-2023-0090029, filed on Jul. 11, 2023 in the Korean Intellectual Property Office, the disclosures of which are incorporated by reference herein in their entireties.

### TECHNICAL FIELD

The inventive concept relates to a wafer abnormality detection method and a semiconductor device manufacturing method using the same. More particularly, the inventive concept relates to a wafer abnormality detection method using a machine learning model and a semiconductor device manufacturing method using the wafer abnormality detection method.

### DISCUSSION OF RELATED ART

The manufacturing processes for semiconductor devices are highly integrated, necessitating the development of advanced three-dimensional profile measurement technologies. These technologies are used for producing fine patterns and complex structures in semiconductor devices. Recently, particularly in the production of memory and logic products, microprocessing technologies capable of achieving line widths of 20 nm or less have been used. Consequently, the significance of a technology for monitoring a micropattern formation process has grown, playing an important role in improving manufacturing yield and quality. In particular, the importance of an abnormality detection method to determine defects in a semiconductor device process is emerging.

### SUMMARY

The inventive concept relates to a wafer abnormality detection method with improved measurement reliability and a semiconductor device manufacturing method using the same.

The inventive concept relates to a wafer abnormality detection method with improved measurement reliability for structural characteristics of a wafer pattern and a semiconductor device manufacturing method using the same.

According to an embodiment of the inventive concept, there is provided a wafer abnormality detection method including: calculating a residual spectrum between a measured spectrum for a wafer and a predicted spectrum for the wafer; and performing machine learning to determine whether measurement data, which corresponds to the residual data, is abnormal.

According to an embodiment of the inventive concept, there is provided a wafer abnormality detection method including: obtaining a measured spectrum for a wafer; obtaining a predicted spectrum for the wafer; calculating a residual spectrum that is a difference between the measured spectrum and the predicted spectrum; performing a variable separation algorithm with respect to the residual spectrum; generating a machine learning model by using setup data; and determining whether measurement data is abnormal by using the generated machine learning model, wherein the measurement data includes data about the residual spectrum.

According to an embodiment of the inventive concept, there is provided a semiconductor device manufacturing method including: performing a first semiconductor process on a wafer; obtaining a measured spectrum on the wafer; obtaining a predicted spectrum for the wafer; calculating a residual spectrum that is a difference between the measured spectrum and the predicted spectrum; performing a variable separation algorithm with respect to the residual spectrum; generating a machine learning model by using setup data that is normal data; determining whether measurement data is abnormal by using the generated machine learning model, wherein the measurement data includes data about the residual spectrum; and performing a second semiconductor process on the wafer.

### BRIEF DESCRIPTION OF THE DRAWINGS

Embodiments of the inventive concept will be more clearly understood from the following detailed description taken in conjunction with the accompanying drawings in which:

FIG. 1 is a diagram illustrating a wafer abnormality detection system according to an embodiment;

FIG. 2 is a diagram illustrating a wafer abnormality detection system according to an embodiment;

FIG. 3 is a schematic diagram illustrating spectral ellipsometry (SE) according to an embodiment;

FIGS. 4 and 5 are flowcharts illustrating a semiconductor device abnormality detection method according to an embodiment;

FIG. 6 illustrates graphs for describing a method of calculating residual spectrum data according to an embodiment;

FIG. 7 is a graph illustrating support vector machine (SVM) modeling performed by a second sub-model according to an embodiment;

FIG. 8 is a flowchart illustrating a machine learning modeling method performed by a second sub-model according to an embodiment;

FIG. 9 is a graph illustrating a normality index of each piece of measurement data according to an embodiment;

FIG. 10 is a graph illustrating a normality index per process according to an embodiment;

FIG. 11 is a flowchart illustrating a semiconductor device manufacturing method using a wafer abnormality detection method according to an embodiment;

FIG. 12 is a block diagram illustrating an integrated circuit and a device including the same according to an embodiment; and

FIG. 13 is a block diagram illustrating a system including a machine learning model device according to an embodiment.

### DETAILED DESCRIPTION OF THE EMBODIMENTS

Hereinafter, embodiments of the inventive concept will be described in detail with reference to the accompanying drawings. Like reference numerals may refer to like elements, and their repetitive descriptions may be omitted.

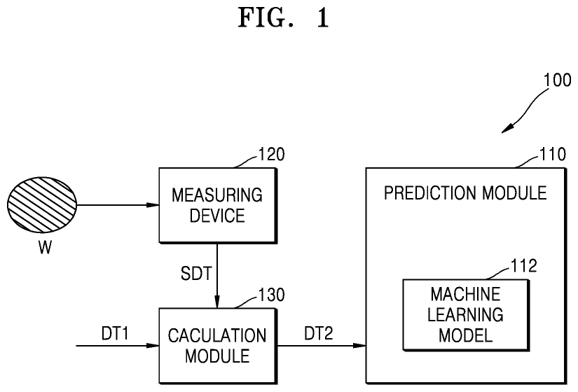

FIG. 1 is a diagram illustrating a wafer abnormality detection system 100 according to an embodiment.

Referring to FIG. 1, the wafer abnormality detection system 100 may include a prediction module 110, a measuring device 120, and a calculation module 130. The prediction module 110 may be implemented in hardware as a circuit. The calculation module 130 may be implemented in hardware as a circuit. The wafer abnormality detection system 100 may detect abnormal data on a wafer W that has undergone a semiconductor process. In addition, the wafer abnormality detection system 100 may further include general-purpose components such as memory, a communication module, a video module (for example, a camera interface, a joint photographic experts group (JPEG) processor, a video processor, or a mixer), a three-dimensional (3D) graphics core, an audio system, a display driver, a graphics processing unit (GPU), and a digital signal processor (DSP).

The prediction module 110 may analyze input data based on an artificial intelligence (AI) method to predict a pattern formed on the wafer W based on the analyzed data. Additionally, the prediction module 110 may control configurations of a wafer abnormality detection device in which it is employed. For example, the prediction module 110 may analyze the input data based on a machine learning method. For example, the prediction module 110 may be applied to a simulator used for modeling or monitoring an object in a computing system, a mobile device, a video display device, a measurement device, or an Internet of things (IoT) device, and may be employed in one of various types of electronic devices.

The prediction module 110 may generate a machine learning model 112, and may train or learn the machine learning model 112. Additionally, the prediction module 110 may perform an operation of the machine learning model 112 based on the received input data, may generate an information signal based on the result of operating the machine learning model 112, or may retrain the machine learning model 112.

The prediction module 110 according to an embodiment may execute the machine learning model 112. The machine learning model 112 is learned to perform specific purpose operations such as predicting the pattern formed on the wafer W, process simulation, and image classification. The prediction module 110 may include the machine learning model 112 used by the wafer abnormality detection system 100 to extract a desired information signal. For example, the machine learning model 112 may include a neural network-based system (for example, a convolution neural network (CNN) or a recurrent neural network (RNN)), a support vector machine (SVM), linear regression, logistic regression, Naive Bayes classification, a random forest, a decision tree, and/or a k-nearest neighbor algorithm.

The machine learning model 112 trained by a learning device (for example, a server that employs machine learning trained on a large amount of input data) may be executed by the prediction module 110. The machine learning model 112 may include one or more parameters. The parameters of the machine learning model 112 may be updated through retraining in the learning device so that the updated machine learning model 112 may be applied to the prediction module 110.

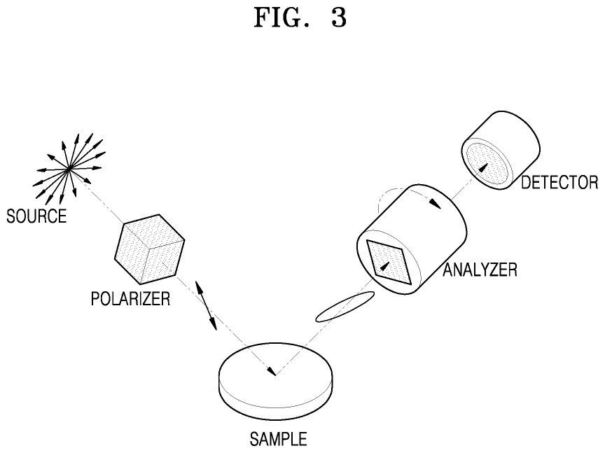

The measuring device 120 may measure structural characteristics of the pattern formed on the wafer W such as a thin film formed on the wafer W. For example, the measuring device 120 may include an ellipsometer. The measuring device 120 may measure a complex refractive index of a material according to a wavelength of light by checking a change in polarization characteristics of light using various techniques. For example, the measuring device 120 may measure a change in polarization state after light is reflected or transmitted, may measure a complex refractive index or a dielectric function tensor, which is a basic physical quantity of a material, based on measured data, and may induce a shape, a crystal state, a chemical structure, and an electrical conductivity of the material. The measuring device 120 may generate spectrum signal data SDT based on the wafer W. The spectrum signal data SDT generated by the measuring device 120 may be referred to as a measured spectrum. An example configuration of the measuring device 120 will be described in detail with reference to FIG. 3.

The calculation module 130 may generate second data DT2 based on the spectrum signal data SDT provided by the measuring device 120 and first data DT1. The first data DT1 may include predicted spectrum data. For example, the calculation module 130 may receive, from a library, a predicted spectrum corresponding to a measurement condition and/or model of a measured spectrum. The calculation module 130 may calculate a residual spectrum that is a difference between the measured spectrum and the predicted spectrum. In another embodiment, the calculation module 130 may simulate the measurement condition and/or model of the measured spectrum to calculate the predicted spectrum.

In addition, the calculation module 130 may use a variable separation algorithm such as a correlation analysis algorithm, a principal component analysis algorithm, or a rank test to extract a profile change value from a spectrum.

The prediction module 110 may train the machine learning model 112 to predict a wafer structure based on the second data DT2 generated by the calculation module 130.

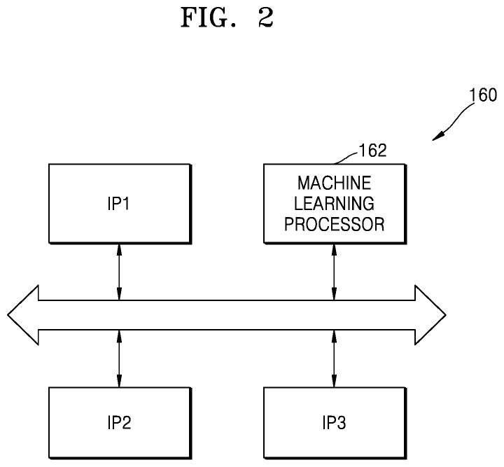

FIG. 2 is a diagram illustrating a wafer abnormality detection system 160 according to an embodiment.

Referring to FIG. 2, the wafer abnormality detection system 160 may analyze input data based on a machine learning model to predict a semiconductor device structure or to monitor a process. For example, the wafer abnormality detection system 160 may be applied to a measurement monitoring system, and may be integrated in one of various types of electronic devices.

The wafer abnormality detection system 160 may include at least one intellectual property (IP) block and a machine learning processor 162. For example, the wafer abnormality detection system 160 may include first, second and third IP blocks IP1, IP2, and IP3 and the machine learning processor 162.

The wafer abnormality detection system 160 may include various types of IP blocks. For example, the IP blocks include a processing unit, a plurality of cores included in the processing unit, a multi-format codec (MFC), a video module (for example, a camera interface, a JPEG processor, a video processor, or a mixer), a three-dimensional (3D) graphics core, an audio system, a driver, a display driver, volatile memory, non-volatile memory, a memory controller, an input and output interface block, and cache memory. Each of the first to third IP blocks IP1, IP2, and IP3 may include at least one of the various types of IP blocks.

Technology for connecting IPs includes a connection method based on a system bus. For example, as a standard bus specification, the advanced microcontroller bus architecture (AMBA) protocol of an advanced reduced instruction set computer (RISC) machine (ARM) may be applied. A bus type of the AMBA protocol may include an advanced high-performance bus (AHB), an advanced peripheral bus (APB), an advanced extensible interface (AXI), AXI4, or AXI coherency extensions (ACE). Among the bus types described above, the AXI as an interface protocol between IPs may provide a multiple outstanding address function and a data interleaving function. In addition, other types of protocols, such as SONICs Inc.'s uNetwork, IBM's CoreConnect, and OCP-IP's Open Core Protocol, may be applied to the system bus.

The machine learning processor 162 may include hardware designed to accelerate and efficiently perform machine learning tasks. For example, the machine learning processor 162 may generate the machine learning model, and may train the machine learning model. Additionally, the machine learning processor 162 may perform an operation based on received input data, may generate an information signal based on the result of the operation, or may retrain the machine learning model.

The machine learning processor 162 may include one or more processors to perform operations according to machine learning models. In addition, the machine learning processor 162 may include additional memory for storing programs corresponding to the machine learning models.

The machine learning processor 162 may receive various types of input data from at least one IP block through the system bus and may generate the information signal based on the input data. For example, the machine learning processor 162 may generate the information signal by performing a machine learning operation on the input data. The machine learning processor 162 may receive various types of input data and may generate a recognition signal according to the input data.

For example, the machine learning processor 162 may further improve semiconductor device structure prediction performance by using an SVM model. Consequently, accuracy of the machine learning processor 162 may be increased.

FIG. 3 is a schematic diagram illustrating spectral ellipsometry (SE) according to an embodiment. SE may be an example of the measuring device 120 of FIG. 1.

SE is an optical technology for investigating structural characteristics such as a thickness of a thin film and a line width of a pattern formed in the thin film, and dielectric characteristics such as a complex refractive index and a dielectric function. Compositions, roughness, thickness, depth, crystalline characteristics, doping concentrations, and electrical conductivities of thin films included in a sample to be inspected may be characterized by SE.

Furthermore, SE is used to determine characteristics of a thin film by comparing a change in polarization before and after interaction with the thin film, such as reflection and transmission, with a model. Here, the change in polarization may be expressed by an amplitude ratio Ψ and a phase difference Δ. The amplitude ratio Ψ refers to a ratio between amplitude changes of a p-wave and an s-wave when light is reflected from the thin film. The phase difference Δ refers to a difference in phase change between the p-wave and the s-wave when light is reflected from the thin film. Because a polarization change depends on a type and thickness of a thin film constituent material, thicknesses and optical constants of all types of films may be measured in a non-contact manner. According to SE, a single atomic layer and a monolayer or multilayer having a thickness ranging from several angstroms to several micrometers may be characterized with high precision.

Referring to FIG. 3, unpolarized electromagnetic radiation emitted by a light source (e.g., Source in FIG. 3) may be linearly polarized by a polarizer (e.g., Polarizer in FIG. 3). Optionally, a compensator, such as a retarder or a quarter wave plate, may be further arranged in an optical path between the polarizer and a sample (e.g., Sample in FIG. 3).

Radiation reflected by the sample may pass through a second polarizer, often called an analyzer (e.g., Analyzer in FIG. 3), before reaching a detector (e.g., Detector in FIG. 3). Likewise, a second compensator may be arranged in the optical path between the analyzer and the sample.

SE is a specular optical inspection method in which an incidence angle is the same as a reflection angle and an incident beam and an reflected beam span an incidence plane. Polarized light in a direction parallel to the incidence plane is referred to as p-polarized light, and polarized light in a direction perpendicular to the p-polarized light is referred to as s-polarized light.

SE measures a complex reflectance ρ, which may be parameterized by a reflection amplitude ratio Ψ and a phase difference Δ. A polarization state of light incident on the sample may be decomposed into s and p components. Amplitudes of the s and p components after reflection, normalized to initial values, are hereinafter denoted as rs and rp, respectively. In this case, rs and rp, and the complex reflectance p satisfy the following equation 1.

$$ρ = \frac{rp}{rs} = tan Φ \cdot {e}^{i Δ} \qquad [ EQUATION 1 ]$$

By selecting the incidence angle of light close to the Brewster angle of the sample, a difference between rp and rs may be maximized. Because SE measures a ratio (or a difference) between the two values, a precise and highly reproducible measurement result may be obtained. Accordingly, SE is relatively insensitive to light scattering and changes in inspection conditions and does not require separate standard samples and reference rays.

Except for exceptionally simple cases such as infinite thickness films or homogeneous films, the measured reflection amplitude ratio Ψ and phase difference Δ cannot be directly converted to the optical constants of the sample. Therefore, in general, model analysis may be performed to obtain an optical constant from the result of the SE. For example, the Forouhi Bloomer model is used. The Forouhi Bloomer model may be based on physical energy transition or free parameters for data fitting. The Forouhi Bloomer model may include the stacking order of layers included in the sample, an optical constant (for example, a refractive index or a dielectric function tensor) and a thickness parameter of each of the individual layers included in the sample.

SE may calculate the reflection amplitude ratio Ψ and the phase difference Δ by using an iteration (for example, a least square) that varies the optical constant and/or thickness parameter. Fresnel's equation may be used to calculate the reflection amplitude ratio Ψ and phase difference Δ. When the calculated reflection amplitude ratio Ψ and phase difference Δ values match experimental data, the corresponding optical constants and thickness values of the thin films may be determined as the optical constants and thicknesses of the thin films included in the sample.

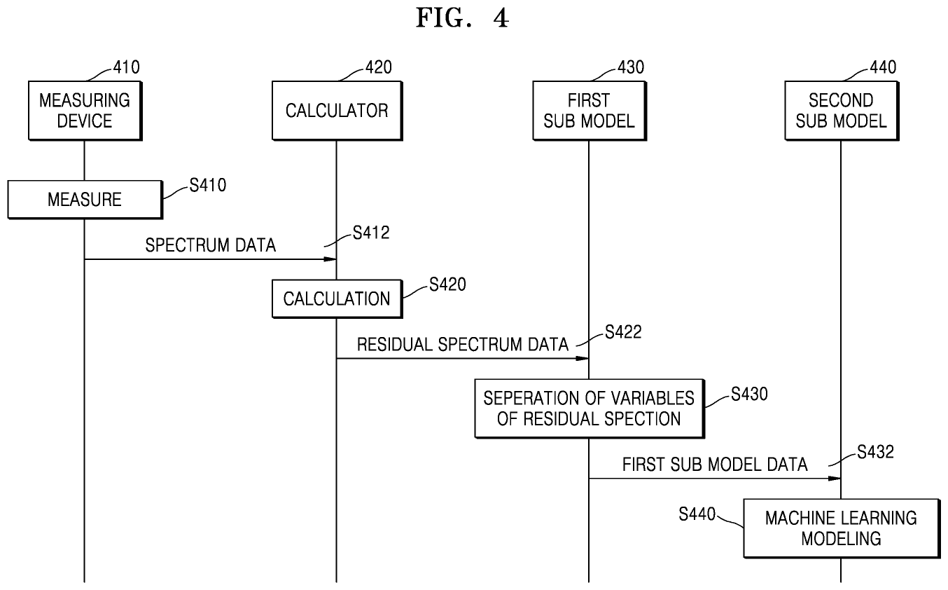

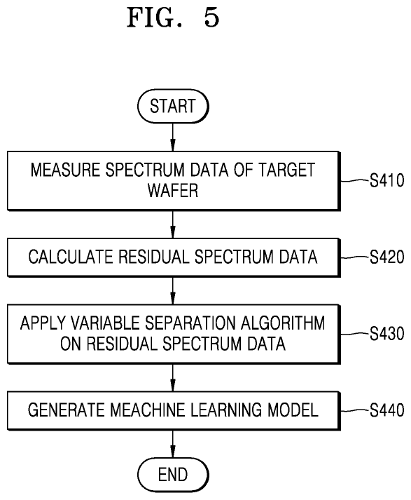

FIGS. 4 and 5 are flowcharts illustrating a semiconductor device abnormality detection method according to an embodiment. Description will be given with reference to FIGS. 1 to 3 together.

To measure a structure of a sample without destroying the sample, a 3D profile measurement technology based on an optical method may be used. The 3D profile measurement technology may include an optical critical dimension (OCD) technology, which is a profile extraction technology that performs electromagnetic analysis of light scattered from a fine pattern. For example, the ellipsometer illustrated in FIG. 3 may measure the structure of the sample by injecting a polarized visible light wavelength into the sample, then measuring and analyzing a reflected spectrum signal.

Referring to FIGS. 4 and 5, a wafer abnormality detection system may include a measuring device 410, a calculator 420, a first sub-model 430, and a second sub-model 440.

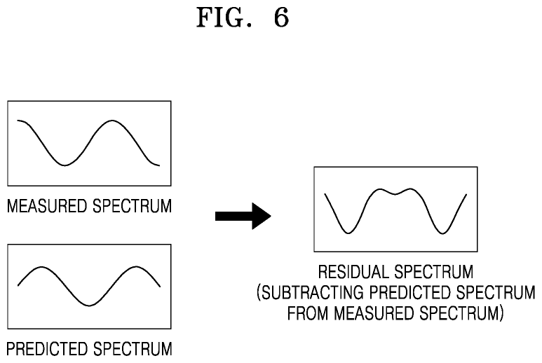

The measuring device 410 may measure spectrum data for the wafer W of FIG. 1 in operation S410. In other words, the measuring device 410 may measure spectrum data of a target wafer. For example, the measuring device 410 may include an optical critical dimension (OCD) facility. The calculator 420 may receive measured spectrum data generated by the measuring device 410 in operation S412. In addition, the calculator 420 may receive predicted spectrum data corresponding to a measurement condition and/or model of the measured spectrum from a library. Then, the calculator 420 may calculate a residual spectrum based on the received measured spectrum data and predicted spectrum data in operation S420. In other words, the calculator 420 may calculate residual spectrum data. The calculator 420 may calculate the residual spectrum data by using a difference between the spectrum data measured by the measuring device 410 and the predicted spectrum data received from the library in operation S420. A method of calculating the residual spectrum data is described in FIG. 6.

FIG. 6 illustrates graphs for describing a method of calculating residual spectrum data according to an embodiment. In each of the graphs of FIG. 6, a horizontal axis represents a wavelength and a vertical axis represents intensity of light.

Referring to FIG. 6, the residual spectrum may be calculated as a difference between the measured spectrum and the predicted spectrum. In other words, by subtracting the predicted spectrum from the measured spectrum, the residual spectrum may be obtained. The measured spectrum may be obtained at a specific position of the wafer W, and the predicted spectrum may correspond to the measurement condition and/or model of the measured spectrum. The residual spectrum may include information on the structure of the wafer W. Therefore, as will be described later, a model for measuring a normality index may be generated by using the residual spectrum.

Returning to FIGS. 4 and 5, for example, it is illustrated that the calculator 420 receives the predicted spectrum from the library and calculates the residual spectrum. However, the inventive concept is not limited thereto. In another embodiment, the calculator 420 may receive the spectrum data generated by the measuring device 410 in operation S412, and may perform a simulation based on the measurement condition and/or model of the received measured spectrum data. The calculator 420 may generate simulation spectrum data and/or simulation wafer structure data through this simulation.

The first sub-model 430 may receive the residual spectrum data generated by the calculator 420 in operation S422. The first sub-model 430 may perform a variable separation algorithm by using the received residual spectrum data as an input in operation S430. For example, it is illustrated that the first sub-model 430 performs a principal component analysis (PCA) algorithm on the residual spectrum data.

The PCA algorithm may reduce a dimension of data. In other words, the PCA algorithm may reduce a dimension of the residual spectrum data. Reducing the dimension of the data may refer to a process of converting high-dimensional data into a low-dimensional representation while maintaining the essential information or structure of original data. In other words, reducing the dimension of the data may refer to reducing the number of variables representing the data.

The PCA algorithm may include calculating a covariance matrix of data and then calculating an eigenvalue based on the calculated covariance matrix. The PCA algorithm may represent data by using some eigenvalues as variables in a high order among the calculated eigenvalues. For example, the variable may be expressed as a linear combination of spectral measurement wavelengths.

For example, the first sub-model 430 may perform the PCA algorithm and then express the analyzed data in a Mueller matrix. The analyzed residual spectrum data may be referred to as measurement data. The Mueller matrix may include information about polarization characteristics of the wafer W. A thickness of the wafer W may be easily analyzed using the Mueller matrix.

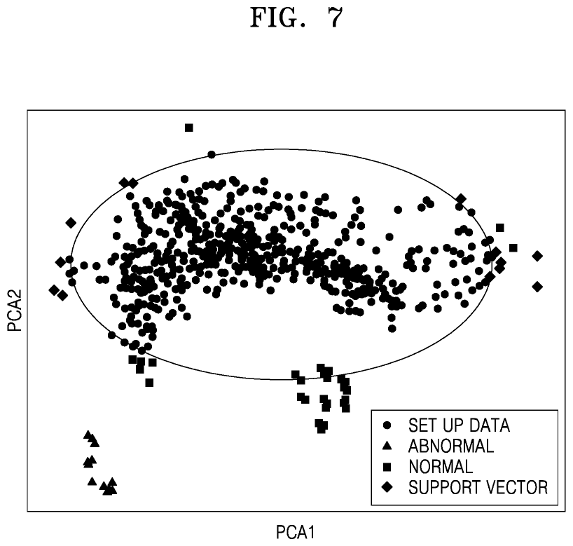

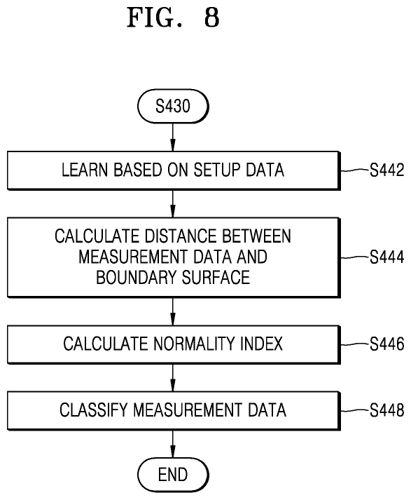

The second sub-model 440 may receive data generated by the first sub-model 430 in operation S432. In other words, the second sub-model 440 may receive first sub-model data. The second sub-model 440 may perform a machine learning modeling based on the received data in operation S440. In other words, the second sub-model 440 may generate a machine learning model. For example, FIGS. 7 and 8 illustrate a case in which the second sub-model 440 performs machine learning modeling based on a one-class support vector machine (OCSVM) algorithm.

FIG. 7 is a graph illustrating SVM modeling performed by the second sub-model 440 according to an embodiment. FIG. 8 is a flowchart illustrating a machine learning modeling method performed by the second sub-model 440 according to an embodiment. Horizontal and vertical axes of the graph of FIG. 7 represent two variables PCA1 and PCA2 selected by the PCA algorithm.

Referring to FIGS. 7 and 8, measurement data and setup data may be arranged on the graph. The measurement data may refer to data on which the variable separation algorithm is performed by the first sub-model 430. In addition, the setup data may be in a preset normal range.

First, learning may be performed based on the setup data in operation S442. The learning may be performed by the one-class SVM (OCSVM) algorithm. As a result of the learning, a boundary may be generated. For example, the OCSVM algorithm may search for a hyperplane that surrounds at least a part of the setup data and is farthest from the origin of the graph. The searched hyperplane may be referred to as a boundary surface. In a process of generating the boundary surface, data that serves as a standard for generating the boundary surface may be classified as a support vector.

Then, a distance between the measurement data and the boundary surface may be calculated with respect to the generated boundary surface in operation S444. Then, a normality index may be calculated according to the distance between the measurement data and the boundary surface in operation S446. The measurement data may be classified according to the calculated normality index in operation S448. When the normality index is no more than a certain value, the data may be determined as abnormal data. Conversely, when the normality index is no less than a certain value, the data may be determined as normal data.

It is illustrated in FIG. 7 that setup data and the measurement data are arranged on a two-dimensional (2D) plane. However, the inventive concept is not limited thereto. For example, the setup data and the measurement data may be arranged on a 3D or greater plane.

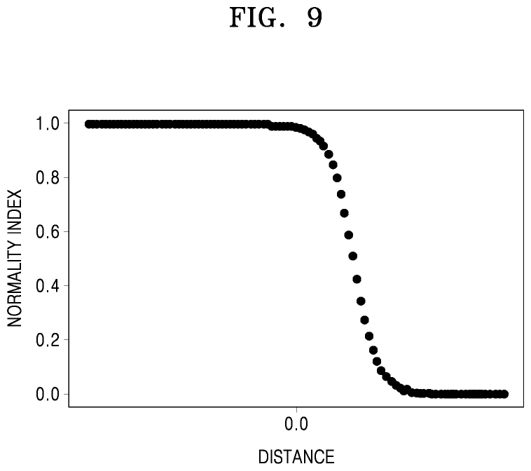

FIG. 9 is a graph illustrating a normality index of each piece of measurement data according to an embodiment. In the graph of FIG. 9, a horizontal axis represents the distance between the boundary surface and the measurement data, and a vertical axis represents the normality index.

Referring to FIG. 9, the normality index may also be referred to as an abnormality index and may have a value of 0 to 1. When the normality index of the measurement data is 1, the measurement data may be determined as normal data, and when the normality index of the measurement data is 0, the measurement data may be determined as abnormal data.

In addition, the distance between the boundary surface and the measurement data may have a positive, zero, or negative value. When the distance between the boundary surface and the measurement data is 0, the measurement data may be positioned at the boundary surface. When the distance between the boundary surface and the measurement data is negative, the measurement data may be positioned in a space defined by the boundary surface. When the distance between the boundary surface and the measurement data is positive, the measurement data may be positioned outside the space defined by the boundary surface.

When the distance between the boundary surface and the measurement data is 0 or less, because the normality index of the measurement data has a value of 1, the measurement data may be determined as normal data. In addition, when the distance between the boundary surface and the measurement data increases in a positive range, the normality index of the measurement data may decrease. Accordingly, when the distance between the boundary surface and the measurement data increases, the probability that the measurement data is determined as abnormal data may increase.

Returning to FIGS. 7 and 8, the second sub-model 440 may be learned by using the setup data, which is labeled data, and the measurement data, which is unlabeled data. In other words, the second sub-model 440 may be trained by a semi-supervised learning method.

In addition, the second sub-model 440 may perform learning by using the setup data, which is normal data, and may classify the measurement data by using the learned model. In addition, because the second sub-model 440 performs learning only by the setup data, which is normal data, the second sub-model 440 may performing learning only by one class that does not include abnormal data. In other words, the second sub-model 440 does not incorporated abnormal data into its learning process.

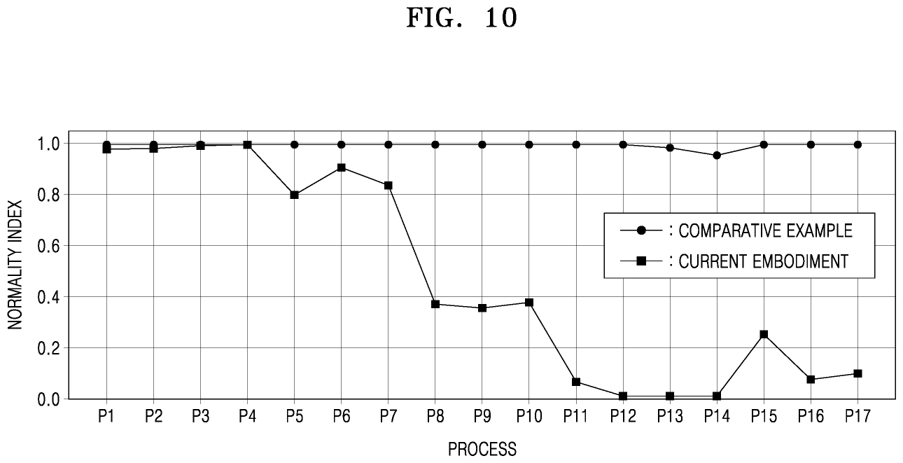

FIG. 10 is a graph illustrating a normality index per process according to an embodiment. In the graph of FIG. 10, circular legends represent normality indexes calculated by a conventional method, and square legends represent normality indexes calculated by the abnormality detection method of the current embodiment. In the graph, a horizontal axis represents a process type (or a process label), and a vertical axis represents a normality index. For example, processes P1, P2, P3, P4, P5, P6, P7, P8, P9, P10, P11, P12, P13, P14, P15, P16 and P17 may have different process types or different process conditions.

Referring to FIG. 10, in the same process, normality indexes according to the existing method and the method of the current embodiment may be measured differently. Compared to the existing method in which a difference in normality index between different processes is relatively small, in the method of the current embodiment, a difference in normality index between different processes may be relatively large. In other words, by the method of the current embodiment, abnormal data may be more precisely classified than by the existing method.

In the existing wafer abnormality detection method, abnormality is detected or a normality index is calculated by a mean square error (MSE) and/or a root mean square error (RMSE) of the measured spectrum and the predicted spectrum. For example, the existing wafer abnormality detection method uses a goodness of fit (GOF) to detect an abnormality or to calculate a normality index.

On the other hand, in the wafer abnormality detection method of the current embodiment, a residual spectrum, which is the difference between the measured spectrum and the predicted spectrum, is calculated, a variable separation algorithm is performed on the residual spectrum, and the processed measurement data is classified by using an SVM method (for example, OCSVM). Accordingly, by performing the abnormality detection method of the current embodiment, abnormal data may be precisely classified from normal data by using a machine learning model.

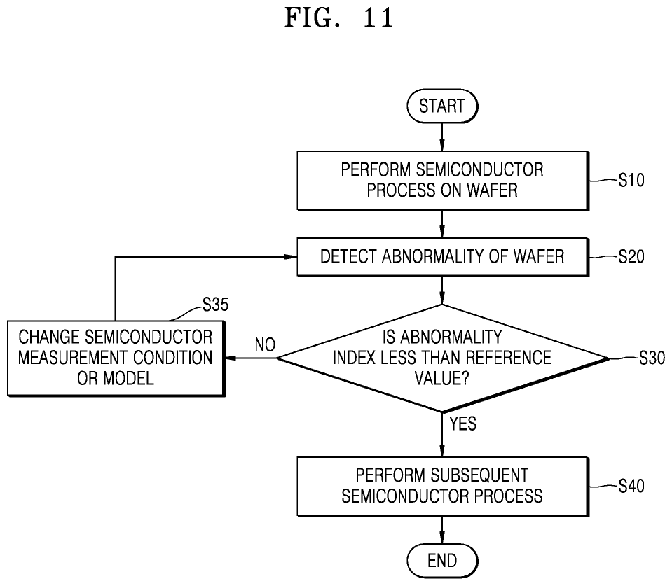

FIG. 11 is a flowchart illustrating a semiconductor device manufacturing method including a wafer abnormality detection method according to an embodiment. Description will be given with reference to FIGS. 1 to 10 together.

Referring to FIG. 11, a semiconductor process may be performed on the wafer W in operation 510. For example, the semiconductor process may include i) an oxidation process to form an oxide film, ii) a lithography process including spin coating, exposure and development, iii) a thin film deposition process, iv) a dry or wet etching process, and v) a metal wiring process.

Then, abnormality detection may be performed on the wafer W that has undergone the semiconductor process in operation S20. The abnormality detection method of the operation S20 may be substantially the same as the wafer abnormality detection method of FIG. 5. In other words, the semiconductor device abnormality detection method of the operation S20 may include receiving spectrum data on a wafer in operation S410, calculating residual spectrum data in operation S420, applying a variable separation algorithm to the residual spectrum data in operation S430, and generating a machine learning model in operation S440.

After detecting abnormality of the wafer W, an abnormality index is compared with a reference value in operation 530. When the abnormality index is greater than the reference value (NO), the process may proceed to operation S35 in which a semiconductor measurement condition and/or model is changed. In this case, operation S20 is performed again. Conversely, when the abnormality index is less than the reference value (YES), a subsequent semiconductor process is performed in operation 540. For example, the normality index is a distance from a boundary interface based on setup data in a PCA space. Conversely, the abnormality index is a 1-normality index and expresses a degree of difference from a normal spectrum model.

The subsequent semiconductor process for the wafer W may include various processes. For example, the subsequent semiconductor process may include a deposition process, an etching process, an ion process, and a cleaning process. In addition, the subsequent semiconductor process may include a singulation process of individualizing the wafer W into each semiconductor chip, a test process of testing semiconductor chips, and a packaging process of packaging the semiconductor chips. The semiconductor device may be completed through a subsequent semiconductor process on the wafer W.

For example, the semiconductor device may include at least one of volatile memory and non-volatile memory. The non-volatile memory includes read only memory (ROM), programmable ROM (PROM), electrically programmable ROM (EPROM), electrically erasable and programmable ROM (EEPROM), flash memory, phase-change random access memory (RAM) (PRAM), magnetic RAM (MRAM), resistive RAM (ReRAM), or ferroelectric RAM (FeRAM). The volatile memory includes dynamic RAM (DRAM), static RAM (SRAM), synchronous DRAM (SDRAM), PRAM, MRAM, ReRAM, or FeRAM. In an embodiment, the semiconductor device may include at least one of a hard disk drive (HDD), a solid state drive (SSD), a compact flash (CF), secure digital (SD), micro-SD, mini-SD, or a memory stick.

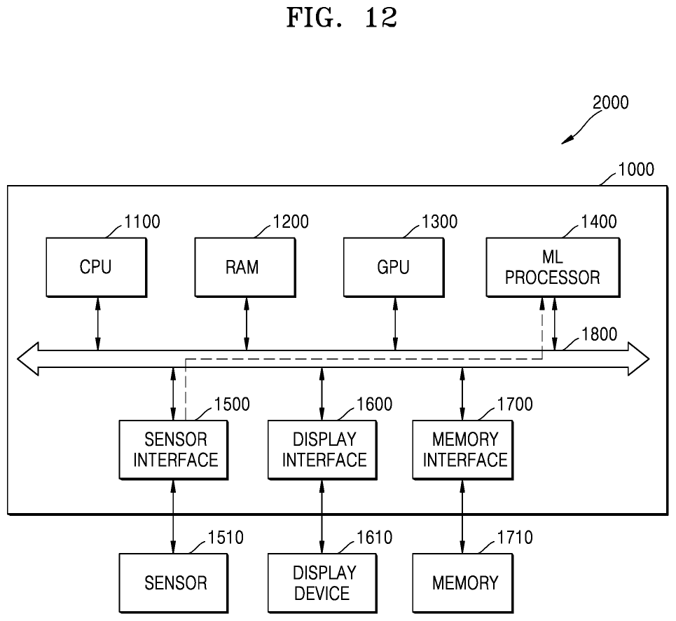

FIG. 12 is a block diagram illustrating an integrated circuit 1000 and a device 2000 including the same according to an embodiment.

Referring to FIG. 12, the device 2000 may include the integrated circuit 1000 and components connected to the integrated circuit 1000, for example, a sensor 1510, a display device 1610, and memory 1710. The device 2000 may process data based on machine learning. For example, the device 2000 may include a mobile device such as a process simulator, a smartphone, a game device, or a wearable device.

The integrated circuit 1000 according to the embodiment may include a central processing unit (CPU) 1100, random access memory (RAM) 1200, a GPU 1300, a machine learning processor 1400, a sensor interface 1500, a display interface 1600, and a memory interface 1700. In addition, the integrated circuit 1000 may further include other components such as a communication module, a digital signal processor (DSP), and a video module, and components (e.g., the CPU 1100, the RAM 1200, the GPU 1300, the machine learning processor 1400, the sensor interface 1500, the display interface 1600, and the memory interface 1700) of the integrated circuit 1000 may transmit and receive data to and from one another through a bus 1800. In an embodiment, the integrated circuit 1000 may include an application processor. In an embodiment, the integrated circuit 1000 may be implemented as a system-on-chip (SoC).

The CPU 1100 may control an overall operation of the integrated circuit 1000. The CPU 1100 may include a processor core or a plurality of processor cores. The CPU 1100 may process or execute programs and/or data stored in the memory 1710. In an embodiment, the CPU 1100 may control a function of the machine learning processor 1400 by executing the programs stored in the memory 1710.

The RAM 1200 may temporarily store programs, data, and/or instructions. According to an embodiment, the RAM 1200 may be implemented as dynamic RAM (DRAM) or static RAM (SRAM). The RAM 1200 may temporarily store data input and output through the sensor interface 1500 and the display interface 1600 or generated by the GPU 1300 or the CPU 1100, for example, image data.

In an embodiment, the integrated circuit 1000 may further include read only memory (ROM). The ROM may store continuously used programs and/or data. The ROM may be implemented as erasable programmable ROM (EPROM) or electrically erasable programmable ROM (EEPROM).

The GPU 1300 may perform image processing on the image data. For example, the GPU 1300 may perform image processing on the image data received through the sensor interface 1500. The image data processed by the GPU 1300 may be stored in the memory 1710 or may be provided to the display device 1610 through the display interface 1600. The image data stored in the memory 1710 may be provided to the machine learning processor 1400.

The sensor interface 1500 may interface data (for example, image data or audio data) input from the sensor 1510 connected to the integrated circuit 1000.

The display interface 1600 may interface data (for example, an image) output to the display device 1610. The display device 1610 may output data on an image through a display such as a liquid crystal display (LCD) or an active matrix organic light emitting diode (AMOLED).

The memory interface 1700 may interface data input from or output to the memory 1710 outside the integrated circuit 1000. According to an embodiment, the memory 1710 may be implemented as volatile memory such as DRAM or SRAM, or non-volatile memory such as ReRAM, PRAM, or a NAND flash. The memory 1710 may be implemented as a memory card such as a multi-media card (MMC), an embedded MMC (eMMC), secure digital (SD), or micro-SD.

The prediction module 110 described in FIG. 1 may be applied as the machine learning processor 1400. The machine learning processor 1400 may receive and learn the measured spectrum data and the predicted spectrum data on the pattern of the wafer W from an external measuring device to predict the structural characteristics of the pattern of the wafer W. The machine learning processor 1400 may be implemented as a circuit.

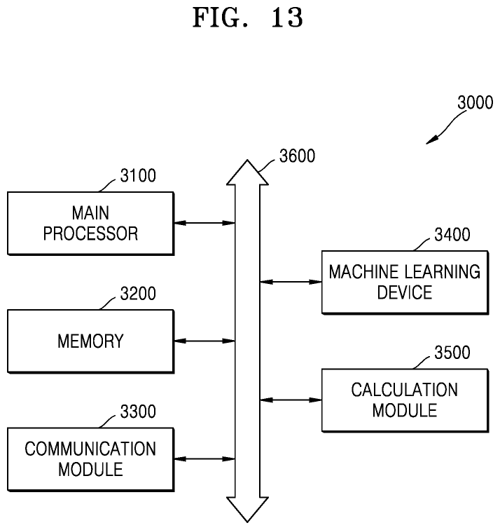

FIG. 13 is a block diagram illustrating a system 3000 including a machine learning model device according to an embodiment.

Referring to FIG. 13, the system 3000 may include a main processor 3100, a memory 3200, a communication module 3300, a machine learning model device 3400, and a calculation module 3500. Components of the system 3000 may communicate with one another through a bus 3600.

The main processor 3100 may control an overall operation of the system 3000. For example, the main processor 3100 may include a CPU. The main processor 3100 may include a core or a plurality of cores. The main processor 3100 may process or execute programs and/or data stored in the memory 3200. For example, the main processor 3100 may control the machine learning model device 3400 to run machine learning by executing the programs stored in the memory 3200.

The communication module 3300 may include various wired or wireless interfaces capable of communicating with an external device. The communication module 3300 may receive a target machine learning model learned from a server, and may also receive a model generated through reinforcement learning. The communication module 3300 may include a wired local area network (LAN), a wireless local area network (WLAN), a wireless personal area network (WPAN) such as Bluetooth, a wireless universal serial bus (USB), Zigbee, near field communication (NFC), radio-frequency identification (RFID), power line communication (PLC), or a communication interface accessible to a mobile cellular network such as 3rd generation (3G), 4th generation (4G), or long term evolution (LTE).

The calculation module 3500 may process various types of input and output data to simulate a semiconductor process. For example, the calculation module 3500 may include equipment for measuring a manufactured semiconductor, and may provide actual measured data to the machine learning model device 3400.

The machine learning model device 3400 may perform machine learning based on measured spectrum data and predicted spectrum data. The wafer abnormality detection system 100 described with reference to FIGS. 1 to 11 may be applied as the machine learning model device 3400. The system 3000 may transmit residual spectrum data, which is a difference between the measured spectrum data and the predicted spectrum data, to the machine learning model device 3400. The machine learning model device 3400 may be trained based on the SVM model. Accordingly, abnormality detection accuracy for a wafer of the system 3000 may be increased.

The device according to the embodiments set forth herein may include a processor, a memory storing and executing program data, a permanent storage such as a disk drive, a communication port communicating with an external device, and a user interface device such as a touch panel, a key, or a button. Methods set forth herein implemented as software modules or algorithms may be stored in a computer-readable recording medium as computer-readable codes or program instructions executable in the processor. Here, the computer-readable recording medium includes a magnetic storage medium (for example, ROM), RAM, a floppy disk, or a hard disk) or an optical reading medium (for example, a compact disc (CD)-ROM or a digital versatile disc (DVD)). The computer-readable recording medium may be distributed among networked computer systems, so that the computer-readable codes may be stored and executed in a distributed manner. The medium may be read by a computer, stored in memory, and executed by a processor.

The embodiments set forth herein may be represented by functional block configurations and various processing operations. These functional blocks may be implemented in various numbers of hardware and/or software configurations executing specific functions. For example, embodiments may employ integrated circuit configurations such as memory, processing, logic, and look-up tables capable of executing various functions under control of one or more microprocessors or other control devices. Similar to how the components may be implemented as software programming or software elements, the embodiments may be implemented in programming or scripting languages such as C, C++, Java, and Assembler, including various algorithms implemented as data structures, processes, routines, or combinations of other programming configurations. Functional aspects may be implemented as algorithms running on one or more processors. In addition, the embodiments may employ conventional technology for electronic environment setting, signal processing, and/or data processing.

While the inventive concept has been particularly shown and described with reference to embodiments thereof, it will be understood that various changes in form and detail may be made thereto without departing from the spirit and scope of the inventive concept as set forth in the following claims.

What is claimed is:

1. A wafer abnormality detection method comprising:
calculating a residual spectrum between a measured spectrum for a wafer and a predicted spectrum for the wafer; and
performing machine learning to determine whether measurement data, which corresponds to the residual data, is abnormal.

2. The wafer abnormality detection method of claim 1, further comprising performing a variable separation algorithm with respect to the residual spectrum.

3. The wafer abnormality detection method of claim 2, wherein the variable separation algorithm comprises a principal component analysis (PCA) algorithm.

4. The wafer abnormality detection method of claim 3, wherein the PCA algorithm is a linear combination of a plurality of wavelengths of the measured spectrum.

5. The wafer abnormality detection method of claim 1, wherein the machine learning comprises a semi-supervised learning model trained by labeled data and unlabeled data.

6. The wafer abnormality detection method of claim 5, wherein the labeled data comprises setup data that is normal data, and
wherein the unlabeled data comprises the measurement data.

7. The wafer abnormality detection method of claim 6, wherein the determining of whether the measurement data is abnormal comprises generating a model by learning from the setup data; calculating a normality index for the measurement data based on the generated model; and determining whether the measurement data is abnormal based on the calculated normality index.

8. The wafer abnormality detection method of claim 1, wherein the wafer is measured by spectral ellipsometry (SE) to obtain the measured spectrum.

9. A wafer abnormality detection method comprising:
obtaining a measured spectrum for a wafer;
obtaining a predicted spectrum for the wafer;
calculating a residual spectrum that is a difference between the measured spectrum and the predicted spectrum;
performing a variable separation algorithm with respect to the residual spectrum;
generating a machine learning model by using setup data; and
determining whether measurement data is abnormal by using the generated machine learning model, wherein the measurement data includes data about the residual spectrum.

10. The wafer abnormality detection method of claim 9, wherein the generating of the machine learning model comprises generating a boundary surface based on the setup data, and
wherein the determining of whether the measurement data is abnormal comprises calculating a normality index of the measurement data.

11. The wafer abnormality detection method of claim 10, wherein, in the performing of the variable separation algorithm, a dimension of the residual spectrum is reduced.

12. The wafer abnormality detection method of claim 10, wherein, in the calculating of the normality index, the normality index is calculated according to a distance between the boundary surface and the data about the residual spectrum.

13. The wafer abnormality detection method of claim 12, wherein the normality index decreases as a distance between the boundary surface and the measurement data increases.

14. The wafer abnormality detection method of claim 10, wherein, when the normality index is not less than a certain value, the measurement data is determined as normal data.

15. The wafer abnormality detection method of claim 10, wherein the generating of the boundary surface further comprises expressing the setup data and the measurement data in a Mueller matrix.

16. The wafer abnormality detection method of claim 9, wherein the setup data comprises only normal data.

17. The wafer abnormality detection method of claim 9, wherein the machine learning model is based on a support vector machine (OCSVM) algorithm.

18. A semiconductor device manufacturing method comprising:
performing a first semiconductor process on a wafer;
obtaining a measured spectrum on the wafer;
obtaining a predicted spectrum for the wafer;
calculating a residual spectrum that is a difference between the measured spectrum and the predicted spectrum;
performing a variable separation algorithm with respect to the residual spectrum;
generating a machine learning model by using setup data that is normal data;
determining whether measurement data is abnormal by using the generated machine learning model, wherein the measurement data includes data about the residual spectrum; and
performing a second semiconductor process on the wafer.

19. The semiconductor device manufacturing method of claim 18, wherein the generating of the machine learning model comprises generating a boundary surface based on the setup data, and
wherein the determining of whether the measurement data is abnormal comprises calculating a normality index according to a distance between the boundary surface and the measurement data.

20. The semiconductor device manufacturing method of claim 18, further comprising changing a measurement condition or model for the wafer when an abnormality index for the wafer is no less than a reference value.
